(19) United States
(12) Patent Application Publication
(10) Pub. No.: US 2024/0284113 A1
(43) Pub. Date: Aug. 22, 2024

(54) Flexible Circuit Board And Multifunctional Acoustic Device

(71) Applicant: AAC Microtech (Changzhou) Co., Ltd., Changzhou (CN)

(72) Inventors: Jinke Liu, Changzhou (CN); Zhijie Dong, Changzhou (CN); Siyuan Ni, Changzhou (CN)

(21) Appl. No.: 18/324,127

(22) Filed: May 25, 2023

Related U.S. Application Data
(63) Continuation of application No. PCT/CN2023/076315, filed on Feb. 16, 2023.

(51) Int. Cl. H04R 9/06; H04R 1/02; H04R 3/00; H04R 9/02; H04R 9/04; H05K 1/02

(52) U.S. Cl. CPC H04R 9/06; H04R 1/025; H04R 3/00; H04R 9/025; H04R 9/045; H05K 1/028; H04R 2400/11

(57) ABSTRACT

The present invention provides a flexible circuit board and a multifunctional acoustic device. The flexible circuit board includes a first fixation portion, a second fixation portion spaced apart from the first fixation portion, and a connection portion connecting the first and the second fixation portion. The connection portion bends and extends obliquely and upwardly from an end of the first fixation portion, so that the connection portion forms a first convex portion higher than a plane of the first fixation portion. The multifunctional acoustic device includes a frame, a magnetic circuit system, a sounding unit, and a motor. The motor includes the flexible circuit board above. By reversely bending the arm of the flexible circuit board, the stress concentration area of the arm is avoided, and the fatigue life of the arm is greatly improved by changing the shape of the arm of the flexible circuit board.

### FIELD OF THE PRESENT INVENTION

The present invention relates to the technical field of electronic device, and more particularly, to a flexible circuit board and a multifunctional acoustic device having the flexible circuit board above.

### DESCRIPTION OF RELATED ART

Whit the rapid development of electronic technology, portable consumer electronic products are becoming more and more popular. In the electronic devices in related art, the elastic arm of the flexible circuit board has a very short fatigue life at the fixation end. In the fatigue reliability test, the concentration stress is easy to concentrate at the fixed position, and in more severe cases, the elastic arm can break. Especially in the electronic device having a motor structure, since part of the structure of the flexible circuit board will vibrate with the motor, there is a higher risk of breakage of the elastic arm.

Therefore, it is desired to provide a new flexible circuit board and a new multifunctional acoustic device having the flexible circuit board which can overcome the above problems.

### SUMMARY

In view of the above, the embodiment of the present invention provides a new flexible circuit board. By the present invention, the stress on the flexible circuit board is dispersed and the life of the flexible circuit board is longer.

The present invention provides a flexible circuit board. The flexible circuit board includes a first fixation portion, a second fixation portion spaced apart from the first fixation portion, and a connection portion connecting the first and the second fixation portion. The connection portion bends and extends obliquely and upwardly from an end of the first fixation portion, so that the connection portion forms a first convex portion higher than a plane of the first fixation portion.

As an improvement, the connection portion bends and extends obliquely and downwardly from an end of the second fixation portion, so that the connection portion forms a second convex portion lower than a plane where the second fixation portion is located.

As an improvement, the first convex portion is an arc structure.

As an improvement, the second convex portion is an arc structure.

In view of the above, the embodiment of the present invention further provides a new multifunctional acoustic device. By the present invention, the stress on the flexible circuit board of the multifunctional acoustic device is dispersed and the life of the multifunctional acoustic device is longer.

The present invention provides a multifunctional acoustic device including a frame, a magnetic circuit system secured to the frame, a sounding unit located on one side of the magnetic circuit system, and a motor located on the other side of the magnetic circuit system. The motor includes a first housing having a receiving room and mounted with the magnetic circuit system, a vibration unit suspended in the receiving room, an elastic support member connecting the vibration unit to the first housing, and a flexible circuit board. The vibration unit includes a supporting plate and a coil fixed on the supporting plate. The flexible circuit board includes a first fixation portion located in the receiving room and connected with the coil, a second fixation portion having a height difference with the first fixation portion, and a connection portion connecting the first fixation portion and the second fixation portion. The second fixation portion locates out of the receiving room. The connection portion bends and extends obliquely and upwardly from an end of the first fixation portion, so that the connection portion forms a first convex portion higher than a plane where the first fixation portion is located.

As an improvement, the connection portion bends and extends obliquely and downwardly from an end of the second fixation portion, so that the connection portion forms a second convex portion lower than a plane where the second fixation portion is located.

As an improvement, wherein the first convex portion is an arc structure.

As an improvement, the second convex portion is an arc structure.

As an improvement, two sides of the first housing are symmetrically provided with a hollow part for the connection portion to extend out of the receiving room.

As an improvement, the sounding unit includes a diaphragm, a voice coil connecting to the diaphragm and driving the diaphragm to vibrate and sound, and a printed circuit board powering for the voice coil, the printed circuit board including a third fixation portion located in the frame and connected with the voice coil, a forth fixation portion located out of the frame and secured with the first housing, and a transition portion connecting the third fixation portion and the forth fixation portion.

### BRIEF DESCRIPTION OF THE DRAWINGS

Many aspects of the exemplary embodiment can be better understood with reference to the following drawing. The components in the drawing are not necessarily drawn to scale, the emphasis instead being placed upon clearly illustrating the principles of the present invention. Moreover, in the drawings, like reference numerals designate corresponding parts throughout the several views.

FIG. 1 is an illustrative isometric view of a multifunctional acoustic device in accordance with one embodiment of the present invention.

FIG. 2 is another isometric view of the multifunctional acoustic device of FIG. 1.

FIG. 3 is a partially exploded view of the multifunctional acoustic device of FIG. 1.

FIG. 4 is an exploded view of the multifunctional acoustic device of FIG. 1.

FIG. 5 is an illustrative isometric view of the flexible circuit board of the multifunctional acoustic device of FIG. 1

FIG. 6 is an illustrative cross-sectional view of the multifunctional acoustic device taken along line A-A of FIG. 1.

### DETAILED DESCRIPTION OF THE EXEMPLARY EMBODIMENT

The present invention will hereinafter be described in detail with reference to an exemplary embodiment. To make the technical problems to be solved, technical solutions and beneficial effects of the present invention more apparent, the present invention is described in further detail together with the figure and the embodiment. It should be understood the specific embodiment described hereby is only to explain the disclosure, not intended to limit the disclosure.

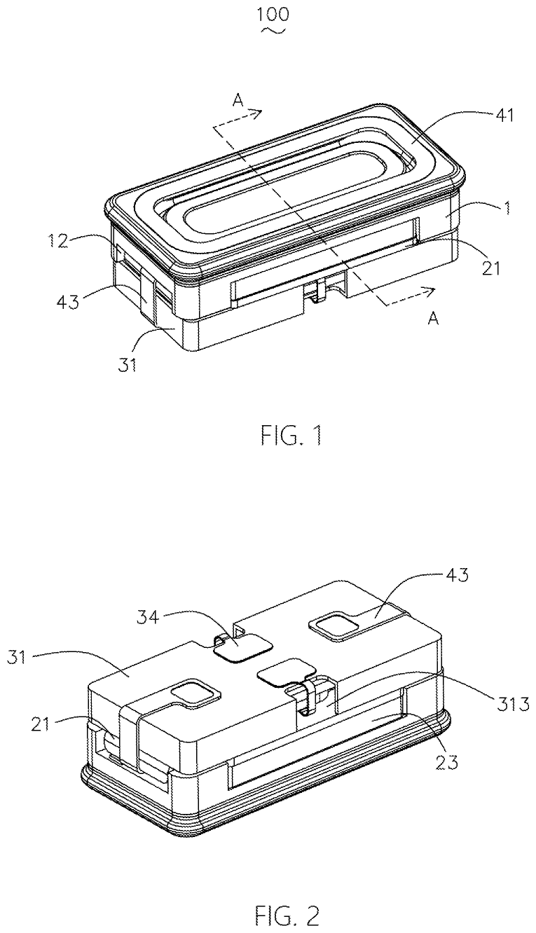

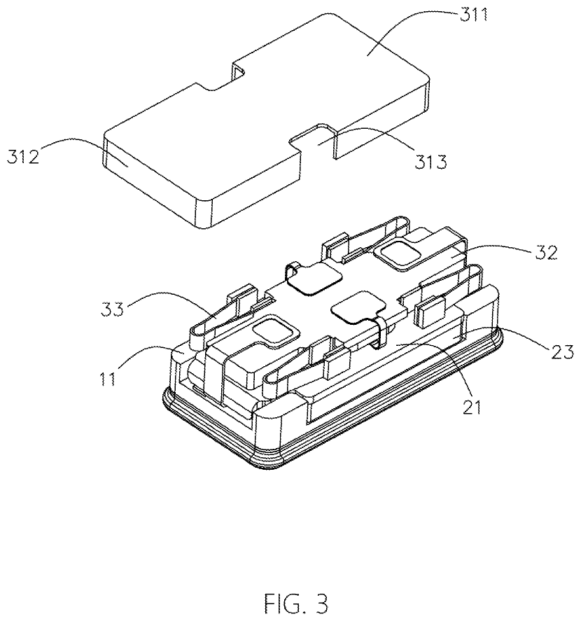

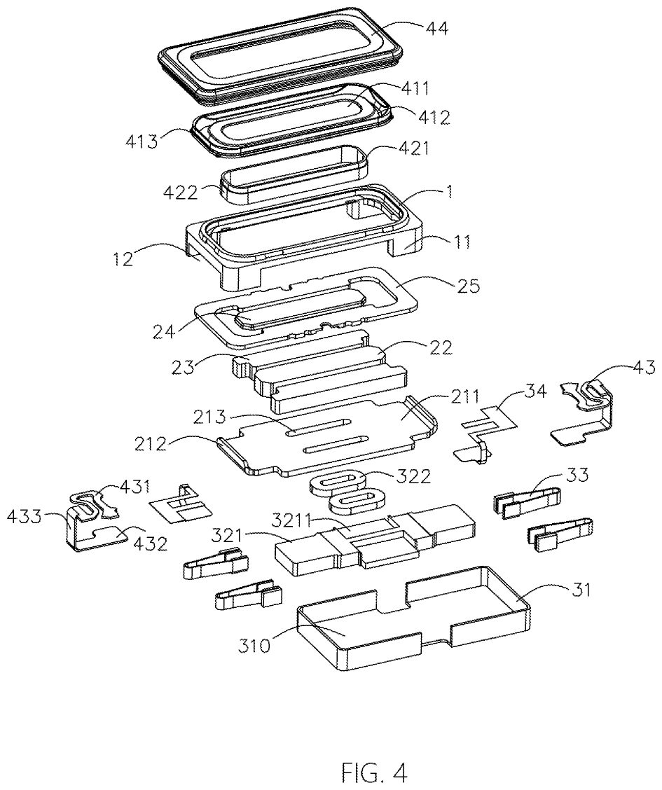

Referring to the FIGS. 1-6, the present invention provides one embodiment of a multifunctional acoustic device 100 which can be used in electronic devices. The multifunctional acoustic device 100 can not only generate sounds, but also function as a motor through vibration. The multifunctional acoustic device 100 includes a frame 1, a magnetic circuit system 2 secured to the frame 1, a motor 3 located on one side of the magnetic circuit system 2, and a sounding unit 4 located on the other side of the magnetic circuit system 2. The multifunctional acoustic device 100 has a rectangular structure.

The frame 1 is a rectangular and annular structure, and the four corners of the frame 1 are provided with a supporting leg 11. A accommodating part 12 is formed between the adjacent supporting legs 11.

The magnetic circuit system 2 includes a magnetic bowl 21, a main magnet 22 mounted on the magnetic bowl 21, a plurality of auxiliary magnets 23 around and spaced apart from the main magnet 22 for forming a magnetic gap, a main pole plate 24 stacked on the main magnet 22, and an auxiliary pole plate 25 stacked on the auxiliary magnets 23. The auxiliary pole plate 25 has an annular structure and is partially embedded in the frame 1. The number of the auxiliary magnet 23 is two, and the two auxiliary magnets 233 are arranged on both sides of the main magnet 22 along a long axis of the multifunctional acoustic device 100.

The magnetic bowl 21 includes a carrying part 211 carrying the main magnet 22 and the auxiliary magnets 23 and an extending part 212 bending and extending from two ends of the carrying part 211. The extending part 212 is received in the accommodating part 12 on a short axis of the multifunctional acoustic device 100. The carrying part 211 has an opening part 213 between two projections of the main magnet 22 and the auxiliary magnets 23. The auxiliary magnets 23 are received in the accommodating part 12 on the long axis of the multifunctional acoustic device 100 and are fixed with the frame 1.

The motor 3 includes a first housing 31 having a receiving room 310 and mounted with the magnetic circuit system 2, a vibration unit 32 suspended in the receiving room 310, an elastic support member 33 connecting the vibration unit 32 to the first housing 31, and a flexible circuit board 34. The first housing 31 includes a bottom wall 311 and a sidewall 312 bending and extending from the bottom wall 311 and form the receiving room 310 with the bottom wall 311. Two sides of the first housing 31 are symmetrically provided with a hollow part 313 along the long axis. The hollow part 313 passes through the sidewall 312 and part of the bottom wall 311 of the first housing 31.

The vibration unit 32 includes a supporting plate 321 and a coil 322 fixed on the supporting plate 321 and vibrating together with the supporting plate 321. The number of the coil 322 is two, and the two coils 322 are symmetrically arranged on both sides of the supporting plate 321. The supporting plate 321 has a receiving slot 3211 for receiving the coil 322. The vibrator unit 32 vibrates along the short axis direction of the multifunctional acoustic device 100 under the action of the magnetic circuit system 2.

The number of the elastic support member 33 is four, and each elastic support members 33 has a V shape. Each side of the vibrator unit 32 is arranged two elastic support members 33. One end of the elastic support member 33 is attached and fixed to the sidewall 312 of the first housing 31, and the other end of the elastic support member 33 is attached and fixed to a side wall of the supporting plate 321.

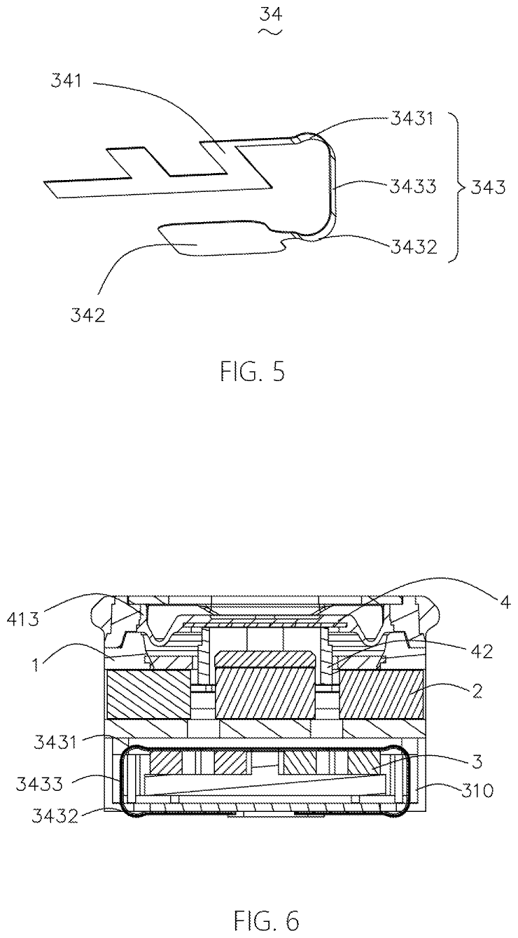

The flexible circuit board 34 includes a first fixation portion 341 located in the receiving room 310 and connected with the coil 322, a second fixation portion 342 locates out of the receiving room 310, and a connection portion 343 connecting the first fixation portion 341 and the second fixation portion 342. The second fixation portion 342 has a height difference with the first fixation portion 341. The first fixation portion 341 is connected to a surface of the coil 322 proximal to the magnetic circuit system 2. The connection portion 343 extends from the hollow part 313 of the first housing 31 out of the first housing 31 and then connects to the second fixation portion 341. The second fixation portion 342 is attached and fixed to an outer surface of the first housing 31. In detail, as shown in FIG. 5, one end of the connection portion 343 bends and extends obliquely and upwardly from an end of the first fixation portion 341, so that the connection portion 343 forms a first convex portion 3431 higher than a plane where the first fixation portion 341 is located. And the other end of the connection portion 343 bends and extends obliquely and downwardly from an end of the second fixation portion 342, so that the connection portion 343 forms a second convex portion 3432 lower than a plane where the second fixation portion 342 is located. The first convex portion 3431 is an arc structure, and the second convex portion 3432 is also an arc structure.

The connection portion 343 further includes a connection arm 3433 connecting the first convex portion 3431 and the second convex portion 3432. The connection arm 3433 can be a smooth arc structure or a flat plate structure. Part of the flexible circuit board 34 is connected with the coil 322 which seen as a part of the vibration unit 32, so part of the flexible circuit board 34 will vibrate together with the coil 322. The flexible circuit board 34 of the present invention can effectively disperse the stress, so that the flexible circuit board 34 is not easy to break while vibrating.

The sounding unit 4 includes a diaphragm 41, a voice coil 42 connecting to the diaphragm 41 and driving the diaphragm 41 to vibrate and sound, a printed circuit board 43 powering for the voice coil 42, and a second housing 44 with fixing the diaphragm 41. The voice coil 42 drives the diaphragm 41 to vibrate and sound along a thickness direction of the multifunctional acoustic device 100 under the action of the magnetic circuit system 2.

The diaphragm 41 includes a dome 411 and a suspension 412 surrounding the dome 411. The suspension 412 has a attached portion 413 attached and fixed to the second housing 44. The voice coil 42 includes a first part 421 connecting with the dome 411 and a second part 422 partially located in the magnetic gap. A thickness of the second part 422 is larger than the thickness of the first part 421.

The printed circuit board 43 includes a third fixation portion 431 located in the frame 1 and connected with the voice coil 42, a forth fixation portion 432 located out of the frame 1 and secured with the first housing 31, and a transition portion 433 connecting the third fixation portion 431 and the forth fixation portion 432.

Comparing with the related art, in the flexible circuit board of the present invention, the flexible circuit board includes a first fixation portion, a second fixation portion spaced apart from the first fixation portion, and a connection portion connecting the first and the second fixation portion. The connection portion bends and extends obliquely and upwardly from an end of the first fixation portion, so that the connection portion forms a first convex portion higher than a plane of the first fixation portion. At the same time, the present invention also provides a multifunctional acoustic device. The multifunctional acoustic device includes a frame, a magnetic circuit system secured to the frame, a sounding unit located on one side of the magnetic circuit system, and a motor located on the other side of the magnetic circuit system. The motor includes a first housing having a receiving room and mounted with the magnetic circuit system, a vibration unit suspended in the receiving room, an elastic support member connecting the vibration unit to the first housing, and a flexible circuit board. The vibration unit includes a supporting plate and a coil fixed on the supporting plate. The flexible circuit board includes a first fixation portion located in the receiving room and connected with the coil, a second fixation portion having a height difference with the first fixation portion, and a connection portion connecting the first fixation portion and the second fixation portion. The second fixation portion locates out of the receiving room. The connection portion bends and extends obliquely and upwardly from an end of the first fixation portion, so that the connection portion forms a first convex portion higher than a plane where the first fixation portion is located.

By the present invention, the connection portion of the flexible circuit board is reversed bent and extended at the position connected with the fixed part, forming a convex portion. The flexible circuit board can further disperse the stress to improve the life of the flexible circuit board. And the life of the multifunctional acoustic device including the flexible circuit board can be also increased.

It is to be understood, however, that even though numerous characteristics and advantages of the present exemplary embodiment have been set forth in the foregoing description, together with details of the structures and functions of the embodiment, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A flexible circuit board, comprising:
a first fixation portion;
a second fixation portion having a height difference with the first fixation portion; and
a connection portion connecting the first fixation portion and the second fixation portion, the connection portion bending and extending obliquely and upwardly from an end of the first fixation portion, so that the connection portion forms a first convex portion higher than a plane where the first fixation portion is located.

2. The flexible circuit board as described in claim 1, wherein the connection portion bends and extends obliquely and downwardly from an end of the second fixation portion, so that the connection portion forms a second convex portion lower than a plane where the second fixation portion is located.

3. The flexible circuit board as described in claim 1, wherein the first convex portion is an arc structure.

4. The flexible circuit board as described in claim 2, wherein the second convex portion is an arc structure.

5. A multifunctional acoustic device, comprising:
a frame;
a magnetic circuit system secured to the frame;
a sounding unit located on one side of the magnetic circuit system; and
a motor located on the other side of the magnetic circuit system, the motor comprising:
a first housing having a receiving room and mounted with the magnetic circuit system;
a vibration unit suspended in the receiving room, the vibration unit comprising:
a supporting plate; and
a coil fixed on the supporting plate;
an elastic support member connecting the vibration unit to the first housing; and
a flexible circuit board, the flexible circuit board comprising:
a first fixation portion located in the receiving room and connected with the coil;
a second fixation portion having a height difference with the first fixation portion, the second fixation portion located out of the receiving room; and
a connection portion connecting the first fixation portion and the second fixation portion, the connection portion bending and extending obliquely and upwardly from an end of the first fixation portion, so that the connection portion forms a first convex portion higher than a plane where the first fixation portion is located.

6. The multifunctional acoustic device as described in claim 5,
wherein the connection portion bends and extends obliquely and downwardly from an end of the second fixation portion, so that the connection portion forms a second convex portion lower than a plane where the second fixation portion is located.

7. The multifunctional acoustic device as described in claim 5, wherein the first convex portion is an arc structure.

8. The multifunctional acoustic device as described in claim 6, wherein the second convex portion is an arc structure.

9. The multifunctional acoustic device as described in claim 5, wherein two sides of the first housing are symmetrically provided with a hollow part for the connection portion to extend out of the receiving room.

10. The multifunctional acoustic device as described in claim 5, wherein the sounding unit comprises a diaphragm, a voice coil connecting to the diaphragm and driving the diaphragm to vibrate and sound, and a printed circuit board powering for the voice coil, the printed circuit board comprising a third fixation portion located in the frame and connected with the voice coil, a forth fixation portion located out of the frame and secured with the first housing, and a transition portion connecting the third fixation portion and the forth fixation portion.
